(19) United States
(12) Patent Application Publication
(10) Pub. No.: US 2024/0409393 A1
(43) Pub. Date: Dec. 12, 2024

(54) MEMS OPTICAL CIRCUIT SWITCH

(71) Applicant: nEYE Systems, Inc., Berkeley, CA (US)

(72) Inventors: Xiaosheng ZHANG, Davis, CA (US); Ming Chiang A. WU, Moraga, CA (US); Tae Joon SEOK, El Cerrito, CA (US); Kyungmok KWON, El Cerrito, CA (US); Noriaki KANEDA, Lafayette, CA (US)

(21) Appl. No.: 18/741,620

(22) Filed: Jun. 12, 2024

Related U.S. Application Data
(60) Provisional application No. 63/507,695, filed on Jun. 12, 2023.

(51) Int. Cl. B81B 3/00; G02B 6/42

(52) U.S. Cl. CPC B81B 3/0083; G02B 6/4286; B81B 2201/045; B81B 2203/0163; B81B 2203/04; B81B 2207/053; B81B 2207/056

(57) ABSTRACT

MEMS optical circuit switches (OCS) are provided herein, which include novel structures and methods for (1) Alignment of the optical components (collimator array, micro-electromechanical systems (MEMS) mirror array, etc.) in a three-dimensional (3D) MEMS optical circuit switch OCS at the time of assembly or calibration; (2) Detection of the mechanical rotation angle of each MEMS mirror in a 3D MEMS OCS using strain sensors; (3) Monitoring and compensation of the long-term MEMS mirror rotation angle drift and system alignment drift of a 3D MEMS OCS; and (4) Fabrication and assembly of a 2-directional MEMS mirror with piezoelectric actuators.

### PRIORITY CLAIM

This patent application claims priority to U.S. provisional patent application No. 63/507,695, titled “MEMS OPTICAL CIRCUIT SWITCH,” and filed on Jun. 12, 2023, which is herein incorporated by reference in its entirety.

### FIELD

The present disclosure details novel MEMS optical circuit switches.

### BACKGROUND

The paper Urata, Ryohei, et al. “Mission Apollo: Landing optical circuit switching at datacenter scale.” arXiv preprint arXiv: 2208.10041 (2022), as well as related patents from Google, describe a 3D MEMS OCS based on electrostatic actuators. The mirror rotation angles are monitored by an illumination-imaging system composed of lasers, infrared cameras, and dichroic mirrors. The Google control scheme uses a monitoring channel that injects each MEMS mirror array with 850 nm light which is received at a matching camera module. A servo uses the camera image feedback to optimize MEMS actuation for minimum loss of the optical signal path. This configuration requires a pair of injection/camera modules for each 2D MEMS array.

The electrostatic actuators described in the above referenced paper have lower output force and thus require high actuation voltage to rotate the MEMS mirrors. The angle monitoring system requires additional lasers and cameras, increasing the size and limiting the scalability of the OCS. The dichroic mirrors may also increase the insertion loss of the OCS.

### SUMMARY OF THE DISCLOSURE

A micro-electromechanical systems (MEMS) optical circuit switch (OCS) is provided, comprising: a first optical fiber array and a second optical fiber array each having N ports; a first MEMS mirror array and a second MEMS mirror array disposed in an optical path between the first optical fiber array and the second optical fiber array, the first and second MEMS mirror arrays each having N mirrors; and a group of MEMS piezoelectric actuators operatively coupled to each of the N mirrors in the first and second MEMS mirror arrays, each group of MEMS piezoelectric actuators being controllable to actuate its corresponding mirror to establish a one-to-one mapping between the ports of the first and second optical fiber arrays.

In some aspects, each of the N mirrors of the first and second MEMS mirror arrays are supported by a mirror base.

In one aspect, MEMS springs are provided for coupling the group of MEMS piezoelectric actuators to each mirror base. In some aspects, the MEMS springs comprise serpentine springs or double folded beam springs.

In some aspects, each group of MEMS piezoelectric actuators comprises strain sensors configured to measure a rotation angle of its corresponding mirror.

In one aspect, the first and second MEMS mirror arrays are disposed on first and second substrates.

In some aspects, the OCS comprises first and second CMOS dies bonded to the first and second substrates, respectively, each of the first and second CMOS dies comprising CMOS control circuits configured to control operation of the first and second MEMS mirror arrays.

In some aspects, the OCS comprises through silicon vias in the first and second substrates configured to provide electrical control signals from the CMOS control circuits to each group of MEMS piezoelectric actuators.

In other aspects, the OCS comprises one or more temperature sensors configured to measure an ambient temperature surrounding the first or second MEMS mirror arrays, wherein temperature data from the one or more temperature sensors is used to compensate for a temperature effect on optical alignment of the first and second MEMS mirror arrays.

In some aspects, the first and second optical fiber arrays include one or more redundant ports dedicated as monitor channels.

In one aspect, the one or more monitor channels carry a monitor light with a constant input power.

In other aspects, the monitor channels are configured to detect long-term angle drift of the first and second MEMS mirror arrays.

In some aspects, the OCS comprises one or more optical power meters configured to measure light power from each of the one or more monitor channels.

In additional aspects, the rotation angle of each mirror is controlled to compensate for the long-term angle drift.

In some aspects, each of the MEMS piezoelectric actuators comprises a first electrode layer deposited on a silicon layer, a piezoelectric material deposited on the first electrode layer, and a second electrode layer deposited on the piezoelectric material.

In another aspect, the OCS includes an insulation layer deposited between the silicon and first electrode layers.

In some aspects, the group of MEMS piezoelectric actuators are configured to provide two-directional rotation of the mirrors of the first and second MEMS mirror arrays.

In additional aspects, two-directional rotation is achieved by adjusting a height the MEMS piezoelectric actuators.

In one aspect, the first and second optical fiber arrays are coupled to first and second collimator arrays, respectively.

A method of aligning an optical circuit switch is provided, comprising: inputting light into all ports of an optical fiber array to direct the light towards a MEMS mirror array; imaging the light in the MEMS mirror array; and adjusting a rotation of the MEMS mirror array based on the imaging to position the light within a desired position within each mirror of the MEMS mirror array.

In some aspects, the desired position comprises a center of each mirror.

A method of aligning an optical circuit switch is provided, comprising: inputting light into all ports of a first optical fiber array to direct the light towards a first MEMS mirror array and a second MEMS mirror array; imaging the light in the first MEMS mirror array with a first camera; imaging the light in the second MEMS mirror array with a second camera; adjusting a rotation of the first MEMS mirror array based on the first camera imaging to position the light within a desired position within each mirror of the first MEMS mirror array; and adjusting a rotation of the second MEMS mirror array based on the second camera imaging to position the light within a desired position within each mirror of the second MEMS mirror array.

In some aspects, the desired position comprises a center of each mirror.

A method of correcting drift of an optical circuit switch is provided, comprising: outputting monitor light from one or more monitor channels of an optical fiber array towards a MEMS mirror array; receiving the monitor light from the MEMS mirror array with one or more optical power meters corresponding to the one or more monitor channels; measuring light power received by the one or more optical power meters; and adjusting a rotation angle of the MEMS mirror array based on the measured light power.

In some aspects, the rotation angle of the MEMS mirror array is adjusted to minimize insertion loss from the one or more monitor channels.

In one aspect, adjusting the rotation angle comprises adjusting tunable mounts of the MEMS mirror array.

In some aspects, adjusting the rotation angle comprises controlling rotation of each mirror of the MEMS mirror array.

### BRIEF DESCRIPTION OF THE DRAWINGS

The novel features of the invention are set forth with particularity in the claims that follow. A better understanding of the features and advantages of the present invention will be obtained by reference to the following detailed description that sets forth illustrative embodiments, in which the principles of the invention are utilized, and the accompanying drawings of which:

FIGS. 1A-1B show the cross-sectional structure of a 3D MEMS OCS based on 2-directional MEMS mirror arrays.

FIG. 2 shows the 3D structure of the 3D MEMS OCS based on 2-directional MEMS mirror arrays.

FIGS. 3A-3C show some examples of different 3D MEMS OCS structures.

FIGS. 4A-4C shows the setup and procedures to align the components in a 3D MEMS OCS when the system is assembled or calibrated.

FIG. 5 shows the schematic of the MEMS mirror angle control system. The rotation angle of each MEMS mirror is monitored by a 2-directional angle sensor.

FIGS. 6A-6B show that in addition to the regular channels carrying optical communication signals, one or more redundant ports on the fiber/collimator arrays and the MEMS mirror arrays can be dedicated as monitor channels.

FIG. 7 shows an example of the OCS structure that includes dedicated monitor channels.

FIG. 8 shows another example of the OCS structure that includes dedicated monitor channels.

FIGS. 9A-9D shows the schematics of each 2-directional MEMS mirror.

FIGS. 10A-10E show that strain sensors can be used to measure the rotation angle of the MEMS mirror.

FIG. 11 shows an example of the MEMS mirror array integrated with a CMOS control circuit.

FIGS. 12A-12B show two examples of a detailed piezoelectric actuator structure.

### DETAILED DESCRIPTION

This disclosure provides novel structures and methods for: (1) Alignment of the optical components (collimator array, micro-electromechanical systems (MEMS) mirror array, etc.) in a three-dimensional (3D) MEMS optical circuit switch (OCS) at the time of assembly or calibration; (2) Detection of the mechanical rotation angle of each MEMS mirror in a 3D MEMS OCS using strain sensors; (3) Monitoring and compensation of the long-term MEMS mirror rotation angle drift and system alignment drift of a 3D MEMS OCS; and (4) Fabrication and assembly of a 2-directional MEMS mirror with piezoelectric actuators.

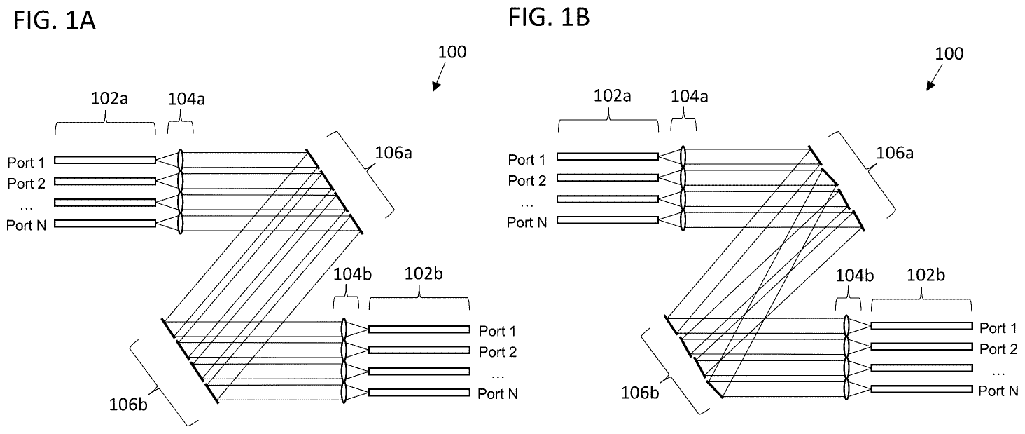

FIGS. 1A-1B show cross-sectional structures of a 3D MEMS OCS 100 based on 2- directional MEMS mirror arrays. The OCS 100 comprises first and second optical fiber arrays 102a/102b with first and second corresponding collimator arrays 104a/104b, and first and second MEMS mirror arrays 106a/106b. Each fiber array has N ports, and each MEMS mirror array has N corresponding mirrors matching the optical paths of the N fiber/collimator channels.

By controlling the angles of each individual MEMS mirror in the arrays, optical beam paths can be configured to establish a one-to-one mapping between the ports in the two fiber arrays. Any possible one-to-one mapping between the two fiber arrays can be achieved by configuring the MEMS mirror arrays.

In FIG. 1A, all MEMS mirrors in the first and second mirror arrays are in neutral positions. In this configuration, each port on the first optical fiber array 102a is mapped to a corresponding port of the second optical fiber (e.g., port 1 mapped to port 1, port 2 mapped to port 2, port N mapped to port N, etc.). However, in FIG. 1B, one or more of the MEMS mirrors in the first and second mirror arrays are actuated to steer the light beam to different angles, establishing a different switch connection configuration. In this configuration, any port in the first optical array can be mapped to any chosen port in the second optical array. For example, in FIG. 1B, port 1 of the first optical fiber array 102a is mapped to port 1 of the second optical fiber array 102b, port 2 of the first optical fiber array 102a is mapped to port N of the second optical fiber array 102b, and port 3 of the first optical fiber array 102a is mapped to port 2 of the second optical fiber array 102b.

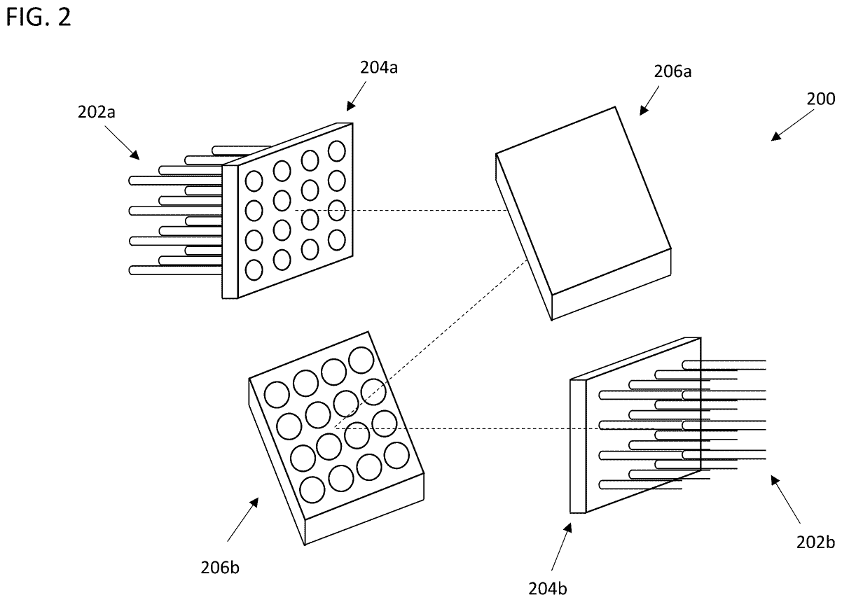

FIG. 2 shows a 3D perspective-view schematic of 3D MEMS OCS 200 based on 2-directional MEMS mirror arrays. This OCS 200 can correspond, for example, to the OCS 100 of FIGS. 1A-1B. The optical fibers in the fiber array and the MEMS mirrors in the MEMS mirror array may be arranged in a rectangular array, a hexagonal array, or other types of array grids. As described above, the OCS 200 can include first and second optical fiber arrays 202a/202b, first and second corresponding collimator arrays 204a/204b, and first and second MEMS mirror arrays 206a/206b.

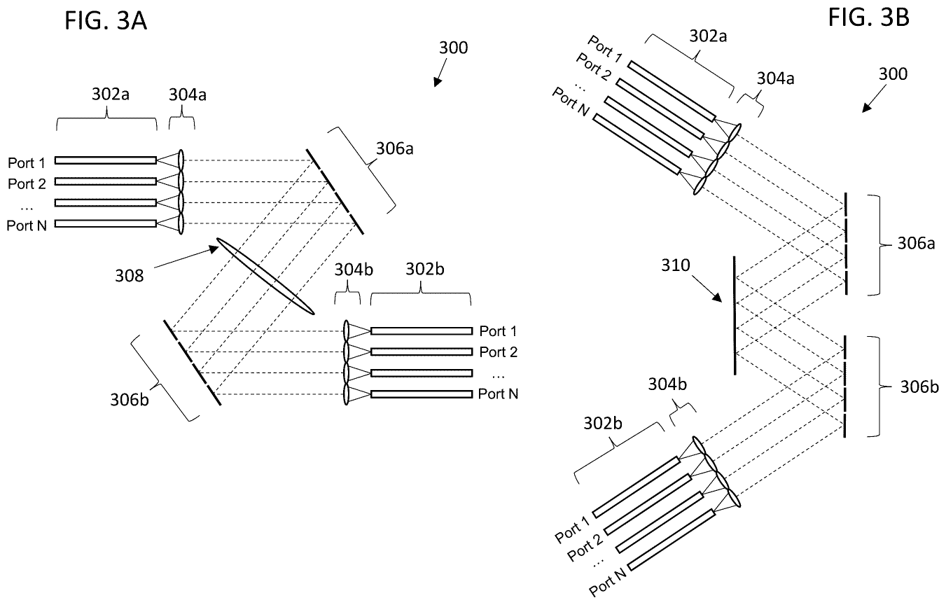

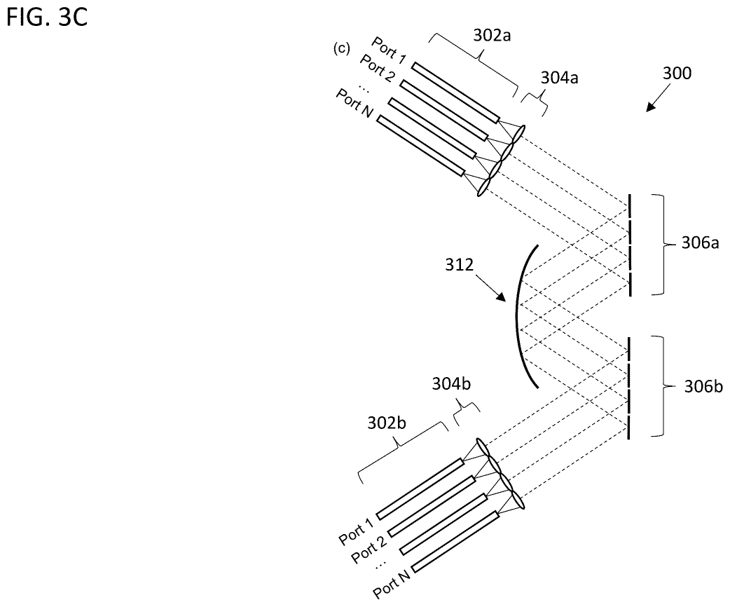

FIGS. 3A-3C show some examples of additional structures incorporated into a 3D MEMS OCS 300, the structures being positioned in the optical path between the first and second MEMS mirror arrays. The OCS 300 can include the same components described above, including first and second optical fiber arrays 302a/302b, first and second corresponding collimator arrays 304a/304b, and first and second MEMS mirror arrays 306a/306b. In FIG. 3A, one or more lenses 308, such as a Fourier lens, may be positioned in the optical path between first MEMS mirror array 306a and second MEMS mirror array 306b. In FIG. 3B, one or more reflector mirrors 310 may be positioned in the optical path between first MEMS mirror array 306a and second MEMS mirror array 306b. Similarly, in FIG. 3C, one or more concave mirrors 312 may be positioned in the optical path between first MEMS mirror array 306a and second MEMS mirror array 306b. These structures, including the lenses and mirrors described above, may be included in the 3D MEMS OCS 300 to help adjust the MEMS mirror rotation angle, control the beam waist location, and/or achieve a different geometric layout.

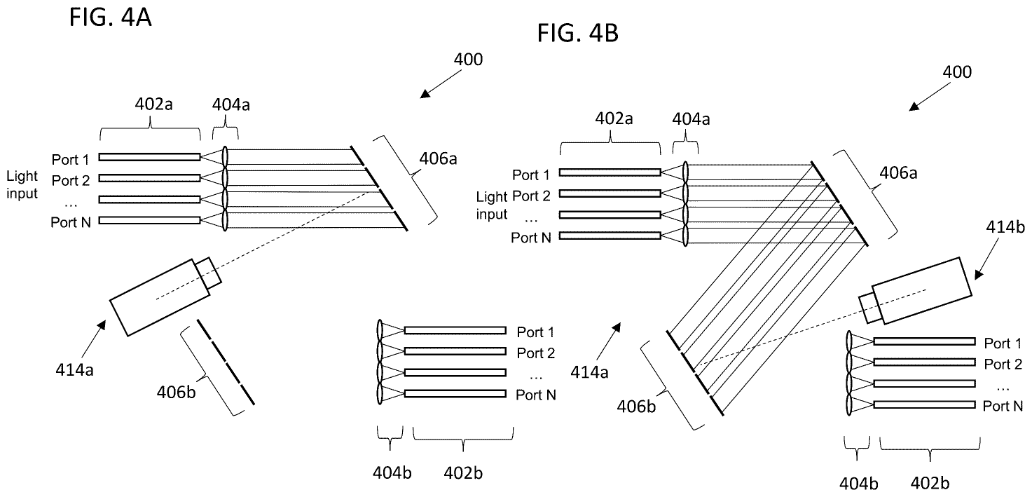

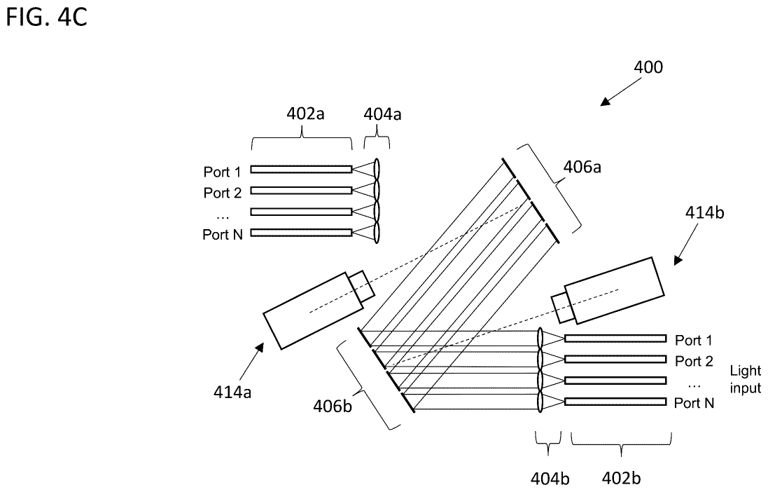

FIGS. 4A-4C show one embodiment of setup and procedures to align the components in a 3D MEMS OCS 400 when the system is assembled or calibrated. The OCS 400 can include the same components described above, including first and second optical fiber arrays 402a/402b, first and second corresponding collimator arrays 404a/404b, and first and second MEMS mirror arrays 406a/406b. Additionally, the OCS can include a first and second infrared cameras 414a/414b to image each MEMS mirror array (e.g., arrays 406a/406b, respectively). The cameras may be configured to capture images at a near-infrared wavelength that is also used for optical communication signals, or capture thermal images at a far-infrared wavelength. Detailed alignment procedures are described below.

As shown in FIG. 4A, light is input from all the ports of the first optical fiber array 402a. First camera 414a is used to image at the first MEMS mirror array 406a. The relative positions between the first optical fiber array 402a/collimator array 404a and the first MEMS mirror array 406a can be adjusted based on image(s) of the first camera 414a such that beam spots of the input light are located within a desired position (e.g., at the center) of the corresponding MEMS mirrors of the first MEMS mirror array 406a.

As shown in FIG. 4B, second camera 414b can be used to image at the second MEMS mirror array 406b. The relative positions between the second optical fiber array 402b/collimator array 404b and the second MEMS mirror array 406b is adjusted based on image(s) of the second camera 414b such that beam spots of the input light are located within a desired position (e.g., at the center) of the corresponding MEMS mirrors of the second MEMS mirror array 406b.

As shown in FIG. 4C, light is input from all the ports of the second optical fiber array 402b. The first camera 414a is used to image at the first MEMS mirror array 406a, and the second camera 414b is used to image at the second MEMS mirror array 406b. The position of the second optical fiber array 402b/collimator array 404b is adjusted so that in image(s) of both the first and second cameras 414a/414b, beam spots of the input light are located at the center of the corresponding MEMS mirror arrays.

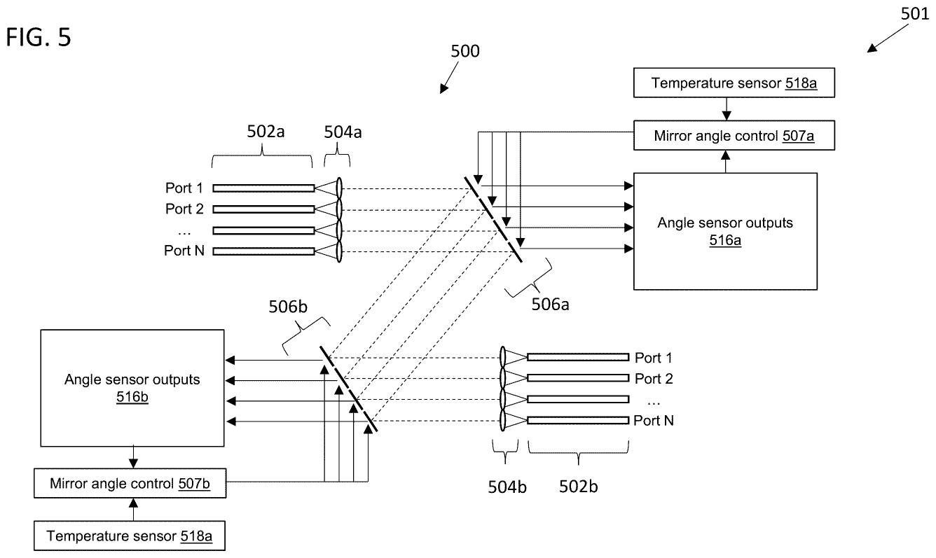

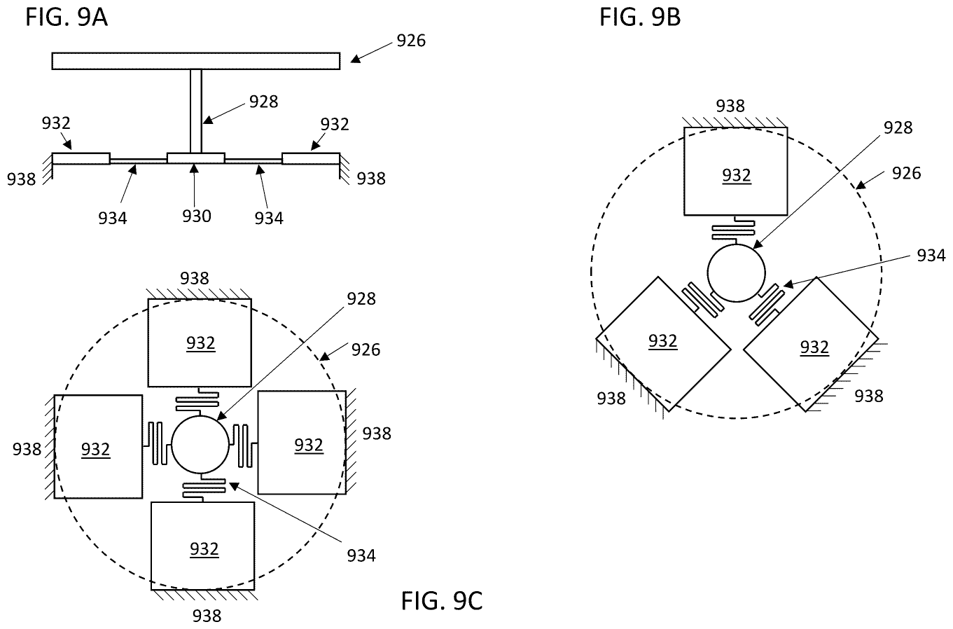

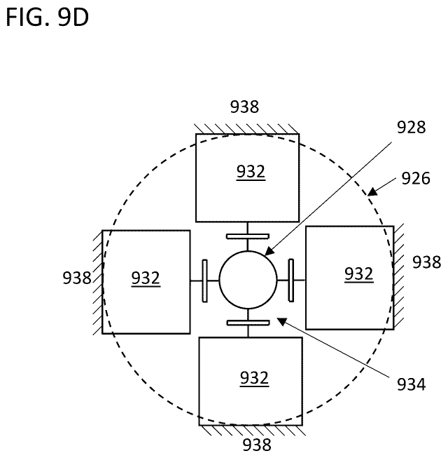

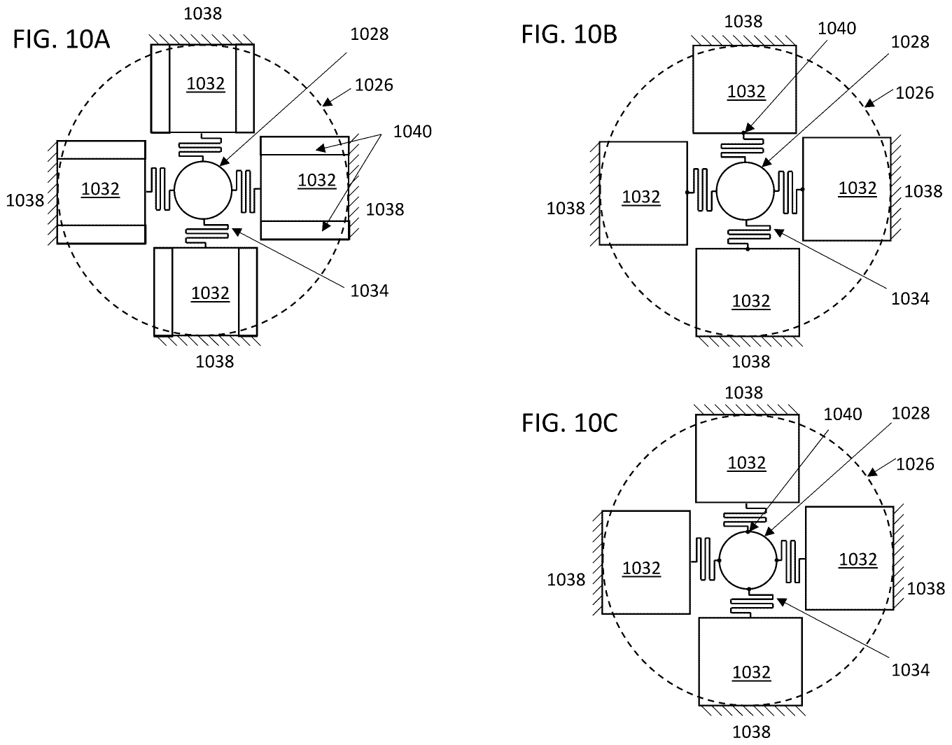

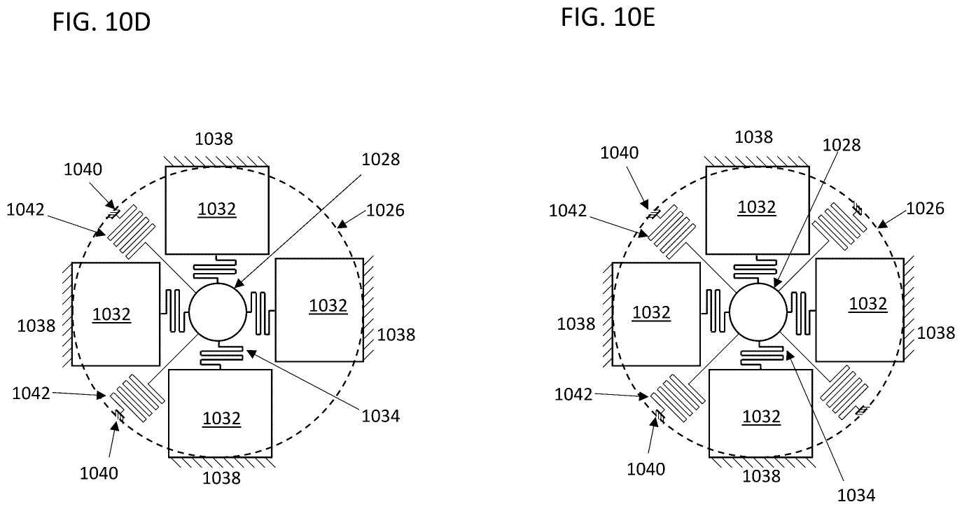

FIG. 5 shows the schematic of a MEMS mirror angle control system 501 for controlling a 3D MEMS OCS 500, such as any of the OCS described herein. As described above, the OCS may include first and second optical fiber arrays 502a/502b, first and second corresponding collimator arrays 504a/504b, and first and second MEMS mirror arrays 506a/506b. First and second MEMS mirror arrays 506a/506b may be controlled by a Mirror angle control 507a/507b, respectively, which can comprise, for example, a processor, controller, or microcontroller. The rotation angle of each MEMS mirror within the MEMS mirror arrays is monitored by an angle sensor (e.g., a 2-directional angle sensor). Detailed implementation of the angle sensor is described below in FIGS. 9 and 10. The angle sensor output data 516a/516b is sent to the appropriate mirror angle control system (e.g., 507a/507b). The mirror angle control system (507a/507b) may be implemented, for example, on a CMOS integrated circuit die or on a printed circuit board with off-the-shelf packaged IC chips. The rotation angle of each MEMS mirror in the first and second MEMS mirror arrays 506a/506b can be controlled to the specific value that establishes the desired optical connection mapping between the two optical fiber arrays 502a/502b. A temperature sensor (e.g., 518a/518b) may be used to measure the ambient temperature surrounding the MEMS mirror arrays. Temperature sensor control data from the temperature sensors can be sent to the mirror angle control, so the temperature effect on the optical alignment and MEMS actuation can be calibrated and compensated for based on the temperature measurement(s).

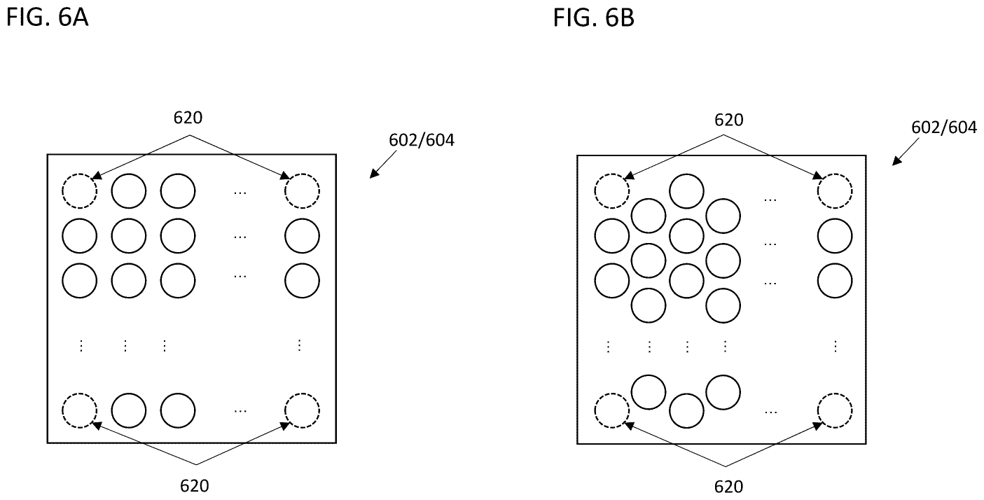

FIGS. 6A-6B shows one embodiment of a fiber/collimator array 602/604 that, in addition to the regular fiber optic channels carrying optical communication signals (solid circles), one or more redundant ports on the fiber/collimator arrays and the corresponding MEMS mirror arrays (not shown) can be dedicated as monitor channels 620. The configuration in FIG. 6A is setup as a rectangular grid, and the configuration in FIG. 6B is setup as a hexagonal grid. In the illustrated examples, the channels at the four corners/perimeter (dashed circles) of the fiber/collimator array can be configured as the monitor channels. In use, the monitor channels may carry a monitor light with a constant input power instead of the regular optical signal. The monitor channels can be used for detecting the long-term angle drift of the overall optical alignment or the drift of the MEMS mirror actuation due to component aging during operations.

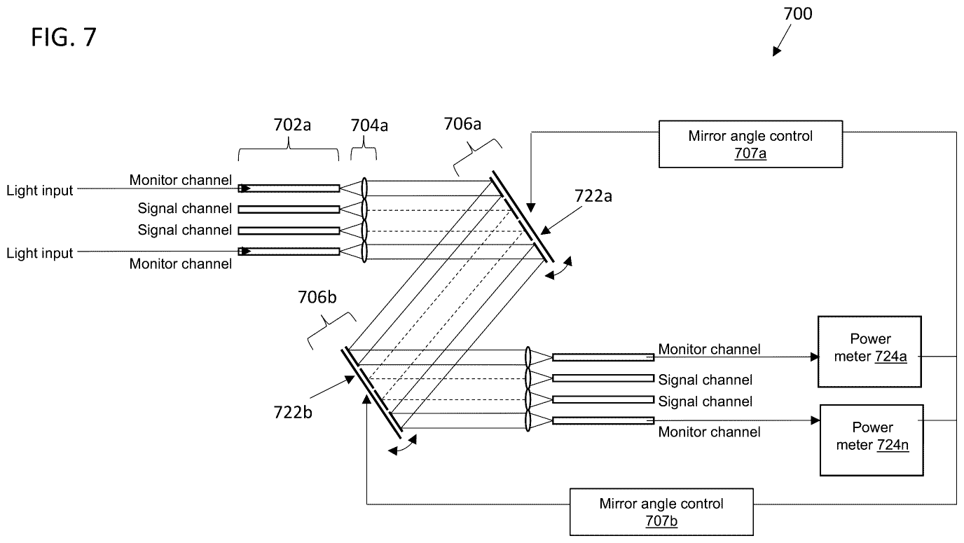

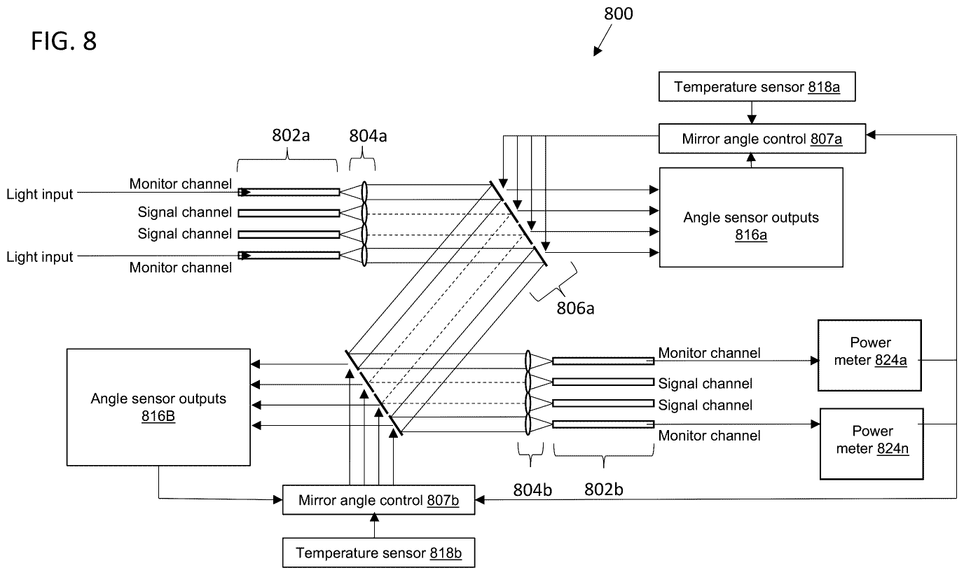

An example of using the monitor channels for a drift compensation procedure is described below using the setup shown in either FIG. 7 or FIG. 8:

FIG. 7 shows an example of the OCS 700 that includes dedicated monitor channels, such as the monitor channels of FIGS. 6A-6B. As described above, the OCS may include first and second optical fiber arrays 702a/702b, first and second corresponding collimator arrays 704a/704b, and first and second MEMS mirror arrays 706a/706b. In this example, each MEMS mirror array is disposed on a 2-directional tunable mount 722a/722b. Light power through the monitor channels is measured by optical power meters 724a-724n, with N being the number of monitor channels. The MEMS mirror mount angles can be adjusted by the mirror angle controls (707a/707b) and tunable mounts 722a/722b based on the measured light power so that the monitor channels have maximum output power, i.e. minimum insertion loss.

FIG. 8 shows another example of the OCS 800 that includes dedicated monitor channels. As described above, the OCS may include first and second optical fiber arrays 802a/802b, first and second corresponding collimator arrays 804a/804b, first and second MEMS mirror arrays 806a/806b, mirror angle controls 807a/807b configured to receive angle sensor inputs 816a/816b, temperature sensors 818a/818b, and power meters 824a-824n. In this example, instead of using a tunable mirror mount of the embodiment of FIG. 7, the drift compensation is achieved by controlling the rotation angle of each MEMS mirror (for example, applying a constant offset angle to every mirror). This drift compensation angle can be superimposed on the regular MEMS mirror angle control system for switch operation.

In one specific embodiment, at the initial assembly of the 3D MEMS OCS, following the setup and procedures described above (e.g., FIGS. 4A-4C), the power meter readings of the monitor channels should be at their maximum when the MEMS mirrors are not actuated. The monitor channels may also be used for fine-tuning the fiber array and MEMS mirror array positions during the initial assembly alignment.

During the long-term OCS operations, the relative positions between the fiber/collimator arrays and the MEMS mirror arrays may be slightly drifted due to mechanical deformation, external shaking or shock, aging of the MEMS mirrors, etc. To compensate for this, at regular time intervals, the system can re-find the monitor channel MEMS mirror angles that can maximize the output power. The maximization procedure can be done with various optimization algorithms, such as a gradient descent algorithm.

The new mirror angles that maximize the output power can be compared with the previous values. These values can then be used to update the mirror mount angle (FIG. 7) or the overall mirror angle offset (FIG. 8).

FIGS. 9A-9D show one embodiment of the schematics of each 2-directional MEMS mirror 926 in the MEMS mirror arrays described herein. FIG. 9A is a side view of the mirror 926, showing the mirror support 928, mirror base 930, piezoelectric actuators 932, springs 934 coupling the mirror base and actuators, and anchors 936. FIGS. 9B-9C are bottom views of two embodiments. The mirror can be fabricated or assembled with a two-layer structure, where the top layer is a metal-coated mirror, and the lower layer includes the supporting, actuating and sensing structures. This design helps increase the mirror fill factor by hiding the actuator underneath the mirror. Three (FIG. 9B) or four (FIG. 9C/9D) piezoelectric actuators 932 that can be vertically actuated are attached to the mirror base 930 via springs 934. In FIGS. 9B-9C, serpentine springs are used, and in FIG. 9D, double folded beam springs are used. Two-directional mirror rotation can be achieved by actuating the actuators to different heights. The required actuator movement is small due to the smaller mirror base size compared to the mirror size.

FIGS. 10A-10E shows embodiments of a MEMS mirror 1026 that include strain sensors 1040 that can be used to measure the rotation angle of the MEMS mirror 1026. FIGS. 10A-10E show bottom views of the mirror 1026, showing the mirror support 1028, mirror base 1030, piezoelectric actuators 1032, springs 1034 coupling the mirror base and actuators, and anchors 1036. The strain sensors may be piezoresistive sensors, or other types of strain sensors. They may be fabricated on the side of the piezoelectric actuators (FIG. 10A), on the actuation serpentine springs (FIGS. 10B-10C), or on additional weak springs 1042 (FIGS. 10D-10E). By measuring the strain on the given locations of the actuators or springs, the actuator or spring deformations can be detected, hence the mirror movement and rotation can be calculated. Each strain sensor location shown in FIGS. 10A-10E may contain one or more strain gauges, which may be electrically configured in bridge circuits (for example, Wheatstone bridge) to detect the strain only in a specific direction.

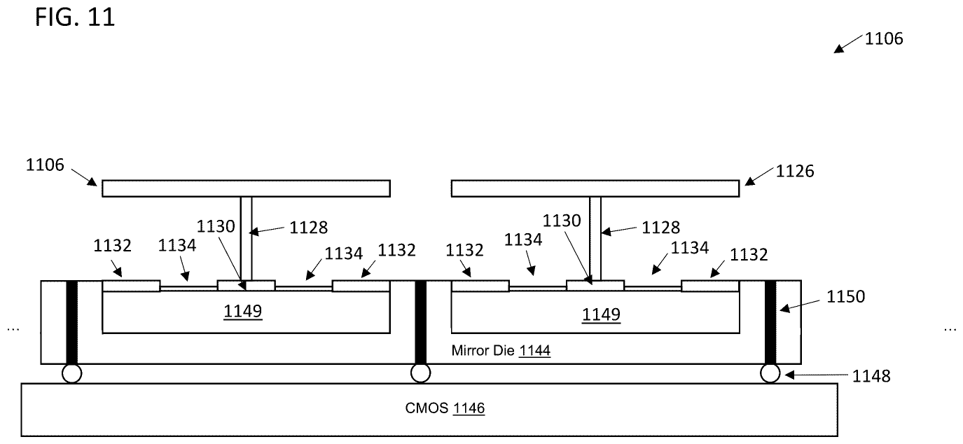

FIG. 11 shows a side view of an example of a MEMS mirror array 1106 integrated with a CMOS control circuit 1144, which can be any of the control circuit designs described herein. The MEMS mirror array can include features previously described, including mirrors 1126, mirror support 1128, mirror base 1130, piezoelectric actuators 1132, and springs 1134 coupling the mirror base and actuators. The MEMS mirror array can be disposed on or within a MEMS mirror die 1144 (e.g., a silicon substrate) which can be bonded to a CMOS die 1146 via bonding pads/balls 1148. Empty space 1149 (e.g., a released area within the MEMS mirror die) allows space for the MEMS structures to move. Electrical signals for the piezoelectric actuators can be supplied from the CMOS die 1146 and connected to corresponding actuators by through-silicon vias 1150.

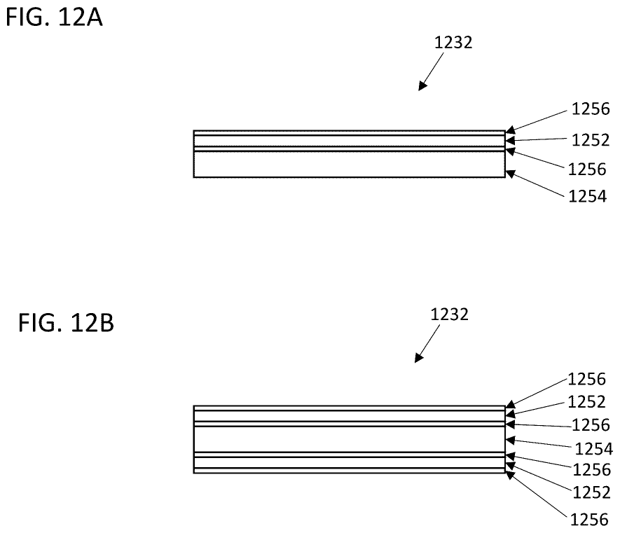

FIGS. 12A-12B show two embodiments of detailed piezoelectric actuator structures 1232. These cross-sectional views can comprise the piezoelectric actuators described above and herein, such as actuators 932/1032/1132. Piezoelectric material 1252 is deposited on the silicon structure layer 1254 with electrode layers 1256 on both sides. An insulation layer may be included between the silicon and electrode layers. The piezoelectric and electrode layers may be fabricated on one side (FIG. 12A) or both sides (FIG. 12B) of the silicon layer.

This disclosure provides the following points of novelty:
(1) Aligning the fiber/collimator arrays with MEMS mirror arrays using cameras.
(2) Monitoring the long-term drift of the OCS with dedicated monitoring channels.
(3) Compensating for long-term drift of the OCS by tuning the MEMS mirror mounts.
(4) Compensating for long-term drift of the OCS by tuning each individual MEMS mirror in the arrays.
(5) Strain sensor placement and configuration for measuring rotation angles of each MEMS mirror.
(6) Two-directional piezoelectric MEMS mirror fabrication and assembly process.

Advantages over prior technology include: (1) Lower actuation voltage by using piezoelectric actuators. (2) Compact system layout by eliminating the camera monitoring system. (3) High MEMS mirror fill factor.

As for additional details pertinent to the present invention, materials and manufacturing techniques may be employed as within the level of those with skill in the relevant art. The same may hold true with respect to method-based aspects of the invention in terms of additional acts commonly or logically employed. Also, it is contemplated that any optional feature of the inventive variations described may be set forth and claimed independently, or in combination with any one or more of the features described herein. Likewise, reference to a singular item, includes the possibility that there are plural of the same items present. More specifically, as used herein and in the appended claims, the singular forms “a,” “and,” “said,” and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Unless defined otherwise herein, all technical and scientific terms used herein have the same meaning as commonly understood by one of ordinary skill in the art to which this invention belongs. The breadth of the present invention is not to be limited by the subject specification, but rather only by the plain meaning of the claim terms employed.

What is claimed is:

1. A micro-electro mechanical systems (MEMS) optical circuit switch (OCS), comprising:
a first optical fiber array and a second optical fiber array each having N ports;
a first MEMS mirror array and a second MEMS mirror array disposed in an optical path between the first optical fiber array and the second optical fiber array, the first and second MEMS mirror arrays each having N mirrors; and
a group of MEMS piezoelectric actuators operatively coupled to each of the N mirrors in the first and second MEMS mirror arrays, each group of MEMS piezoelectric actuators being controllable to actuate its corresponding mirror to establish a one-to-one mapping between the ports of the first and second optical fiber arrays.

2. The OCS of claim 1, wherein each of the N mirrors of the first and second MEMS mirror arrays are supported by a mirror base.

3. The OCS of claim 2, further comprising MEMS springs coupling the group of MEMS piezoelectric actuators to each mirror base.

4. The OCS of claim 3, wherein the MEMS springs comprise serpentine springs.

5. The OCS of claim 1, wherein each group of MEMS piezoelectric actuators comprises strain sensors configured to measure a rotation angle of its corresponding mirror.

6. The OCS of claim 1, wherein the first and second MEMS mirror arrays are disposed on first and second substrates.

7. The OCS of claim 6, further comprising first and second CMOS dies bonded to the first and second substrates, respectively, each of the first and second CMOS dies comprising CMOS control circuits configured to control operation of the first and second MEMS mirror arrays.

8. The OCS of claim 7, further comprising through silicon vias in the first and second substrates configured to provide electrical control signals from the CMOS control circuits to each group of MEMS piezoelectric actuators.

9. The OCS of claim 1, further comprising one or more temperature sensors configured to measure an ambient temperature surrounding the first or second MEMS mirror arrays, wherein temperature data from the one or more temperature sensors is used to compensate for a temperature effect on optical alignment of the first and second MEMS mirror arrays.

10. The OCS of claim 1, wherein the first and second optical fiber arrays include one or more redundant ports dedicated as monitor channels.

11. The OCS of claim 10, wherein the one or more monitor channels carry a monitor light with a constant input power.

12. The OCS of claim 10, wherein the monitor channels are configured to detect long-term angle drift of the first and second MEMS mirror arrays.

13. The OCS of claim 12, further comprising one or more optical power meters configured to measure light power from each of the one or more monitor channels.

14. The OCS of claim 13, wherein the rotation angle of each mirror is controlled to compensate for the long-term angle drift.

15. The OCS of claim 1, wherein each of the MEMS piezoelectric actuators comprises a first electrode layer deposited on a silicon layer, a piezoelectric material deposited on the first electrode layer, and a second electrode layer deposited on the piezoelectric material.

16. The OCS of claim 15, further comprising an insulation layer deposited between the silicon and first electrode layers.

17. The OCS of claim 1, wherein the group of MEMS piezoelectric actuators are configured to provide two-directional rotation of the mirrors of the first and second MEMS mirror arrays.

18. The OCS o claim 17, wherein two-directional rotation is achieved by adjusting a height the MEMS piezoelectric actuators.

19. The OCS of claim 1, wherein the first and second optical fiber arrays are coupled to first and second collimator arrays, respectively.

20. A method of aligning an optical circuit switch, comprising:
inputting light into all ports of an optical fiber array to direct the light towards a MEMS mirror array;
imaging the light in the MEMS mirror array;
adjusting a rotation of the MEMS mirror array based on the imaging to position the light within a desired position within each mirror of the MEMS mirror array.
